(19) United States
(12) Patent Application Publication
(10) Pub. No.: US 2015/0362579 A1
(43) Pub. Date: Dec. 17, 2015

(54) Methods and Systems for Calibrating Sensors Using Recognized Objects

(71) Applicant: Google Inc., Mountain View, CA (US)

(72) Inventor: Joel Hesch, Mountain View, CA (US)

(21) Appl. No.: 14/302,926

(22) Filed: Jun. 12, 2014

(51) Int. Cl. G01R 35/00

(52) U.S. Cl. CPC G01R 35/005

(57) ABSTRACT

Methods and systems for sensor calibration are described. An example method involves receiving image data from a first sensor and sensor data associated with the image data from a second sensor. The image data includes data representative of a target object. The method further involves determining an object identification for the target object based on the captured image data. Additionally, the method includes retrieving object data based on the object identification, where the object data includes data related to a three-dimensional representation of the target object. Additionally, the method includes determining a predicted sensor value based on the based on the object data and the image data. Further, the method includes determining a sensor calibration value based on a different between the received sensor data and the predicted sensor value. Moreover, the method includes adjusting the second sensor based on the sensor calibration value.

### BACKGROUND

In addition to having advanced computing and connectivity capabilities to facilitate high-speed data communication, many modern mobile devices include a variety of sensors. For example, mobile devices, such as smartphones, tablets, and wearable computing devices, are often equipped with sensors for imaging and positioning. A few examples of sensors that may be found in a mobile device include accelerometers, gyroscopes, magnetometers, barometers, global positioning system (GPS) receivers, microphones, cameras, Wi-Fi sensors, Bluetooth sensors, temperature sensors, and pressure sensors, among other types of sensors.

The wide variety of available sensors enables mobile devices to perform various functions and provide various user experiences. As one example, a mobile device may use imaging and/or positioning data to determine a trajectory of the mobile device as a user moves the mobile device through an environment. As another example, a mobile device may use imaging and/or positioning data to generate a 2D or 3D map of an environment, or determine a location of a mobile device within a 2D or 3D map of an environment. As a further example, a mobile device may use imaging and/or positioning data to facilitate augmented reality applications. Other examples also exist.

### SUMMARY

In examples in which a mobile device relies on data from sensors to perform a particular function (e.g., trajectory determination, odometry, map generation, etc.), it can be advantageous to be able to calibrate the data received from the sensors. For example, sensors in a mobile device may be calibrated in a factory setting when the device is manufactured. Described herein are methods and systems for calibrating sensors, including outside of the factory setting. For instance, an end user of a mobile device may capture optical data as either image or video data, this optical data may be used to calibrate the various sensors of the mobile device.

In one example aspect, a method performed by a mobile device having a plurality of sensors is provided. The method involves receiving image data from a first sensor of a plurality of sensors in a mobile device. The image data may include data representative of a target object. The method also includes receiving sensor data determined using a second sensor of the plurality of sensors. The method further includes determining an object identification for the target object, based on the image data. The method also includes retrieving object data based on the object identification. The object data may include data relating to a three-dimensional representation of the object identification. Additionally, the method includes comparing the object data to the data representative of the target object in the image data so as to determine a predicted sensor value to be output from the second sensor corresponding to the first sensor outputting the image data. Further, the method includes determining a sensor calibration value based on a different between the received sensor data and the predicted sensor value. Moreover, the method includes adjusting the second sensor based on the sensor calibration value.

In another example aspect, a mobile device is provided. The mobile device includes at least one camera configured to capture image data, at least one sensor, and a processor. The processor configured to receive image data from the at least one camera. The image data includes data representative of a target object. The processor is also configured to receive sensor data determined using the at least one sensor. The processor is further configured to determine an object identification for the target object based on the image data. After the object identification is determined, the processor is configured to retrieve object data based on the object identification. The object data comprises data relating to a three-dimensional representation of the object identification. Additionally, the processor is configured to compare the object data to the data representative of the target object in the image data so as to determine a predicted sensor value to be output from the second sensor corresponding to the first sensor outputting the image data. Further, the processor is also configured to determine a sensor calibration value based on a different between the received sensor data and the predicted sensor value. The processor is then configured to adjust the at least one sensor based on the sensor calibration value.

In still another example aspect, a non-transitory computer readable medium that, when executed by one or more processors, causes the one or more processors to perform functions is provided. The functions involve receiving image data from a first sensor of a plurality of sensors in a mobile device. The image data may include data representative of a target object. The functions also include receiving sensor data determined using a second sensor of the plurality of sensors. The functions further include determining an object identification for the target object, based on the image data. The functions also include retrieving object data based on the object identification. The object data may include data relating to a three-dimensional representation of the object identification. Additionally, the functions include comparing the object data to the data representative of the target object in the image data so as to determine a predicted sensor value to be output from the second sensor corresponding to the first sensor outputting the image data. Further, the functions include determining a sensor calibration value based on a different between the received sensor data and the predicted sensor value. Moreover, the functions include adjusting the second sensor based on the sensor calibration value.

The foregoing summary is illustrative only and is not intended to be in any way limiting. In addition to the illustrative aspects, embodiments, and features described above, further aspects, embodiments, and features will become apparent by reference to the figures and the following detailed description.

### BRIEF DESCRIPTION OF THE FIGURES

FIG. 1 illustrates an example computing device.

FIG. 2 illustrates another example computing device.

FIGS. 3A-3B are conceptual illustrations of an example computing device.

FIG. 4 is a conceptual illustration of an example mobile device capturing image data of a chair.

FIG. 5 represents example renderings of three a three-dimensional object data for a chair.

FIG. 6 is an example method for device sensor calibration.

FIG. 7A is a flow diagram for an embodiment of the methods disclosed herein.

FIG. 7B is a flow diagram for an embodiment of the methods disclosed herein.

FIG. 8 is schematic illustrating a conceptual partial view of an example computer program product that includes a computer program for executing a computer process on a computing device.

### DETAILED DESCRIPTION

In the following detailed description, reference is made to the accompanying figures, which form a part hereof. In the figures, similar symbols typically identify similar components, unless context dictates otherwise. The illustrative embodiments described in the detailed description, figures, and claims are not meant to be limiting. Other embodiments may be utilized, and other changes may be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

Within examples, a mobile device may be able to capture images and responsively determine sensor calibrations based on the captured images. By way of example, a mobile device may capture at least one image and also capture sensor data along with each image. The mobile device may recognize at least one object from the image. In some examples the mobile may query a database, either local to the device or at a remote location, to obtain information about the object. The information about the object may include three-dimensional object data. The mobile device can then determine associated sensor values based on the three-dimensional object data and the captured image. The associated sensor values may be compared to the captured sensor data to determine a sensor calibration. The determined sensor calibration may then be applied to the associated sensor.

Various examples of the type of information that may be derived from the images and the sensor readings for comparison are described hereinafter. In some examples, a computing device may be able to determine an accuracy of intrinsic and/or extrinsic parameters of the various sensors of the mobile device based on the calculations. Intrinsic parameters may be those parameters that deal with data from a single sensor's output. For example, a bias in a gyroscope unit may be an intrinsic parameter. Extrinsic parameters may be those that describe the ensemble output from the set of sensors. For example, the relative position and orientation of a sensor pair help describe how their measurements coincide when moving through a scene.

In other examples, information derived from other mobile devices may be used to aid in the calibration. As one example, a first mobile device may take a picture. This picture may be communicated to a server. When the second mobile device takes a picture, the server may be able to determine that an object was present in both the first picture from the first device and the second picture from the second device. The calibration for sensors of the second device may be calculated in part based on information associated with the picture from the first device.

Additional example methods as well as example devices (e.g., mobile or otherwise) are described hereinafter with reference to the accompanying figures.

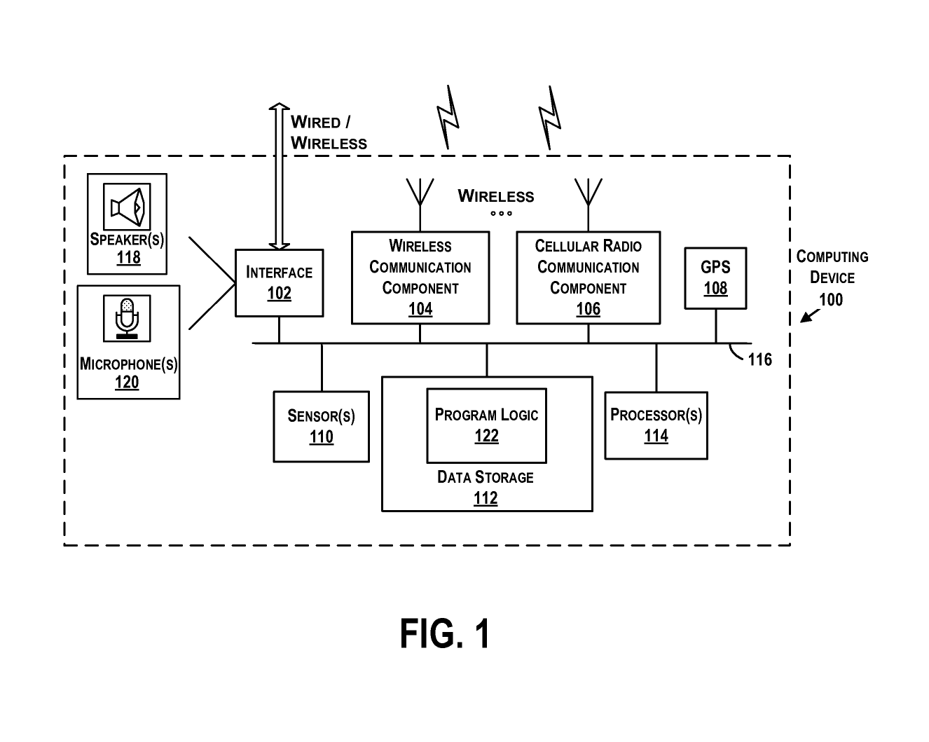

Referring now to the figures, FIG. 1 illustrates an example computing device 100. In some examples, components illustrated in FIG. 1 may be distributed across multiple computing devices. However, for the sake of example, the components are shown and described as part of one example computing device 100. The computing device 100 may be or include a mobile device (such as a mobile phone), desktop computer, laptop computer, email/messaging device, tablet computer, or similar device that may be configured to perform the functions described herein. Generally, the computing device 100 may be any type of computing device or transmitter that is configured to transmit data or receive data in accordance with methods and functions described herein.

The computing device 100 may include an interface 102, a wireless communication component 104, a cellular radio communication component 106, a global positioning system (GPS) receiver 108, sensor(s) 110, data storage 112, and processor(s) 114. Components illustrated in FIG. 1 may be linked together by a communication link 116. The computing device 100 may also include hardware to enable communication within the computing device 100 and between the computing device 100 and other computing devices (not shown), such as a server entity. The hardware may include transmitters, receivers, and antennas, for example.

The interface 102 may be configured to allow the computing device 100 to communicate with other computing devices (not shown), such as a server. Thus, the interface 102 may be configured to receive input data from one or more computing devices, and may also be configured to send output data to the one or more computing devices. The interface 102 may be configured to function according to a wired or wireless communication protocol. In some examples, the interface 102 may include buttons, a keyboard, a touchscreen, speaker(s) 118, microphone(s) 120, and/or any other elements for receiving inputs, as well as one or more displays, and/or any other elements for communicating outputs.

The wireless communication component 104 may be a communication interface that is configured to facilitate wireless data communication for the computing device 100 according to one or more wireless communication standards. For example, the wireless communication component 104 may include a Wi-Fi communication component that is configured to facilitate wireless data communication according to one or more IEEE 802.11 standards. As another example, the wireless communication component 104 may include a Bluetooth communication component that is configured to facilitate wireless data communication according to one or more Bluetooth standards. Other examples are also possible.

The cellular radio communication component 106 may be a communication interface that is configured to facilitate wireless communication (voice and/or data) with a cellular wireless base station to provide mobile connectivity to a network. The cellular radio communication component 106 may be configured to connect to a base station of a cell in which the computing device 100 is located, for example.

The GPS receiver 108 may be configured to estimate a location of the computing device 100 by precisely timing signals sent by GPS satellites.

The sensor(s) 110 may include one or more sensors, or may represent one or more sensors included within the computing device 100. Example sensors include an accelerometer, gyroscope, inertial measurement unit (IMU), pedometer, light sensor, microphone, camera(s), infrared flash, barometer, magnetometer, Wi-Fi, near field communication (NFC), Bluetooth, projector, depth sensor, temperature sensor, or other location and/or context-aware sensors.

The data storage 112 may store program logic 122 that can be accessed and executed by the processor(s) 114. The data storage 112 may also store data collected by the sensor(s) 110, or data collected by any of the wireless communication component 104, the cellular radio communication component 106, and the GPS receiver 108.

The processor(s) 114 may be configured to receive data collected by any of sensor(s) 110 and perform any number of functions based on the data. As an example, the processor(s) 114 may be configured to determine one or more geographical location estimates of the computing device 100 using one or more location-determination components, such as the wireless communication component 104, the cellular radio communication component 106, or the GPS receiver 108. The processor(s) 114 may use a location-determination algorithm to determine a location of the computing device 100 based on a presence and/or location of one or more known wireless access points within a wireless range of the computing device 100. In one example, the wireless location component 104 may determine the identity of one or more wireless access points (e.g., a MAC address) and measure an intensity of signals received (e.g., received signal strength indication) from each of the one or more wireless access points. The received signal strength indication (RSSI) from each unique wireless access point may be used to determine a distance from each wireless access point. The distances may then be compared to a database that stores information regarding where each unique wireless access point is located. Based on the distance from each wireless access point, and the known location of each of the wireless access points, a location estimate of the computing device 100 may be determined.

In another instance, the processor(s) 114 may use a location-determination algorithm to determine a location of the computing device 100 based on nearby cellular base stations. For example, the cellular radio communication component 106 may be configured to identify a cell from which the computing device 100 is receiving, or last received, signal from a cellular network. The cellular radio communication component 106 may also be configured to measure a round trip time (RTT) to a base station providing the signal, and combine this information with the identified cell to determine a location estimate. In another example, the cellular communication component 106 may be configured to use observed time difference of arrival (OTDOA) from three or more base stations to estimate the location of the computing device 100.

In some implementations, the computing device 100 may include a device platform (not shown), which may be configured as a multi-layered Linux platform. The device platform may include different applications and an application framework, as well as various kernels, libraries, and runtime entities. In other examples, other formats or operating systems may operate the computing g device 100 as well.

The communication link 116 is illustrated as a wired connection; however, wireless connections may also be used. For example, the communication link 116 may be a wired serial bus such as a universal serial bus or a parallel bus, or a wireless connection using, e.g., short-range wireless radio technology, or communication protocols described in IEEE 802.11 (including any IEEE 802.11 revisions), among other possibilities.

The computing device 100 may include more or fewer components. Further, example methods described herein may be performed individually by components of the computing device 100, or in combination by one or all of the components of the computing device 100.

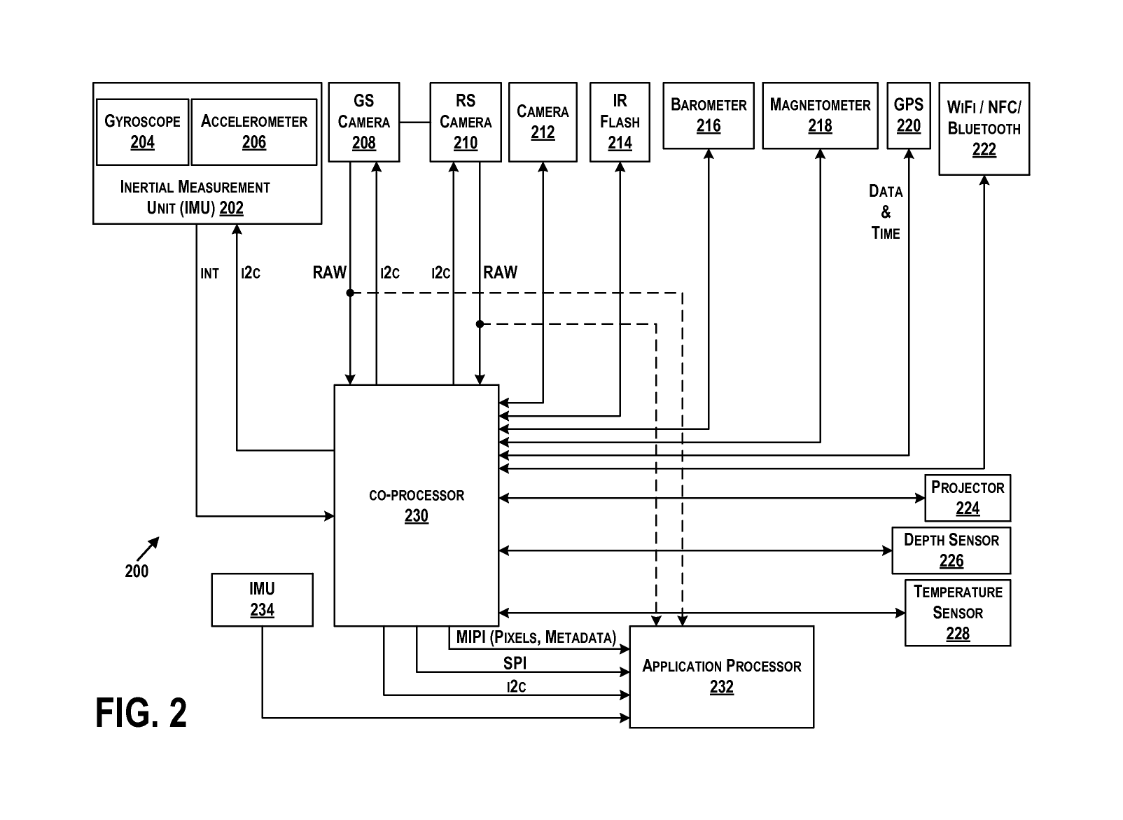

FIG. 2 illustrates another example computing device 200. The computing device 200 in FIG. 2 may be representative of a portion of the computing device 100 shown in FIG. 1. In FIG. 2, the computing device 200 is shown to include a number of sensors such as an inertial measurement unit (IMU) 202 including a gyroscope 204 and an accelerometer 206, a global shutter (GS) camera 208, a rolling shutter (RS) camera 210, a front facing camera 212, an infrared (IR) flash 214, a barometer 216, a magnetometer 218, a GPS receiver 220, a Wi-Fi/NFC/Bluetooth sensor 222, a projector 224, and a temperature sensor 226, each of which outputs to a co-processor 230. Additionally, the computing device 200 is shown to include a depth processor 228 that receives input from and outputs to the co-processor 230. And the co-processor 230 receives input from and outputs to an application processor 232. The computing device 200 may further include a second IMU 234 that outputs directly to the application processor 232.

The IMU 202 may be configured to determine a velocity, orientation, and gravitational forces of the computing device 200 based on outputs of the gyroscope 204 and the accelerometer 206.

The GS camera 208 may be configured on the computing device 200 to be a rear facing camera, so as to face away from a front of the computing device 200. The GS camera 208 may be configured to read outputs of all pixels of the camera 208 simultaneously. The GS camera 208 may be configured to have about a 120-170 degree field of view, such as a fish eye sensor, for wide-angle viewing.

The RS camera 210 may be configured to read outputs of pixels from a top of the pixel display to a bottom of the pixel display. As one example, the RS camera 210 may be a red/green/blue (RGB) infrared (IR) 4 megapixel image sensor, although other sensors are possible as well. The RS camera 210 may have a fast exposure so as to operate with a minimum readout time of about 5.5 ms, for example. Like the GS camera 208, the RS camera 210 may be a rear facing camera.

The camera 212 may be an additional camera in the computing device 200 that is configured as a front facing camera, or in a direction facing opposite of the GS camera 208 and the RS camera 210. The camera 212 may be a wide angle camera, and may have about a 120-170 degree field of view for wide angle viewing, for example.

The IR flash 214 may provide a light source for the computing device 200, and may be configured to output light in a direction toward a rear of the computing device 200 so as to provide light for the GS camera 208 and RS camera 210, for example. In some examples, the IR flash 214 may be configured to flash at a low duty cycle, such as 5 Hz, or in a non-continuous manner as directed by the co-processor 230 or application processor 232. The IR flash 214 may include an LED light source configured for use in mobile devices, for example.

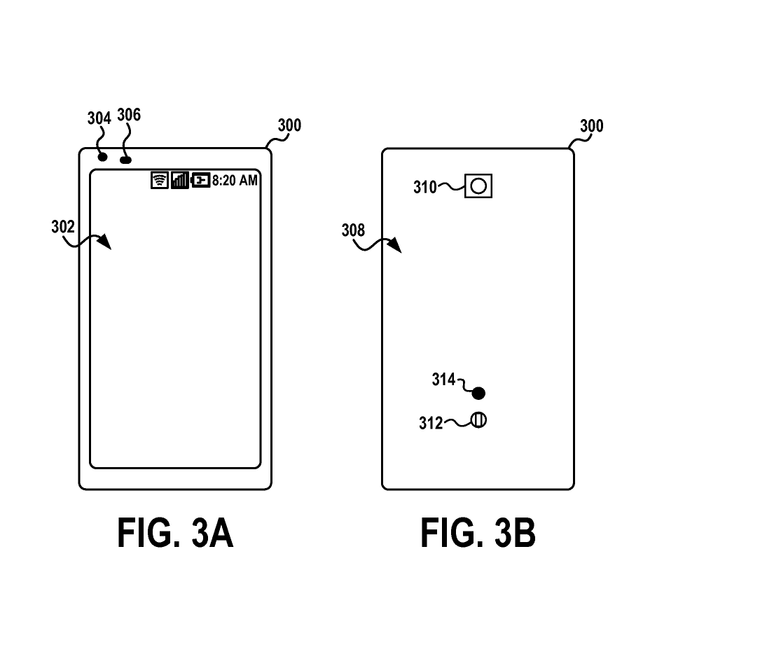

FIGS. 3A-3B are conceptual illustrations of a computing device 300 that show a configuration of some of the sensors on the computing device 300. In FIGS. 3A-3B, the computing device 300 is shown as a mobile phone. The computing device 300 may be similar to either of computing device 100 in FIG. 1 or computing device 200 in FIG. 2. FIG. 3A illustrates a front of the computing device 300 in which a display 302 is provided, along with a front facing camera 304, and a P/L sensor opening 306 (e.g., a proximity or light sensor). The front facing camera 304 may be the camera 212 as described in FIG. 2.

FIG. 3B illustrates a back 308 of the computing device 300 in which a rear camera 310 and another rear camera 314 are provided. The rear camera 310 may be the RS camera 210 and the rear camera 312 may be the GS camera 208, as described in the computing device 200 in FIG. 2. The back 308 of the computing device 300 also includes an IR flash 314, which may be the IR flash 214 or the projector 224 as described in the computing device 200 in FIG. 2. In one example, the IR flash 214 and the projector 224 may be one in the same. For instance, a single IR flash may be used to perform the functions of the IR flash 214 and the projector 224. In another example, the computing device 300 may include a second flash (e.g., an LED flash) located near the rear camera 310 (not shown). A configuration and placement of the sensors may be helpful to provide desired functionality of the computing device 300, for example, however other configurations are possible as well.

Referring back to FIG. 2, the barometer 216 may include a pressure sensor, and may be configured to determine air pressures and altitude changes.

The magnetometer 218 may be configured to provide roll, yaw, and pitch measurements of the computing device 200, and can be configured to operate as an internal compass, for example. In some examples, the magnetometer 218 may be a component of the IMU 202 (not shown).

The GPS receiver 220 may be similar to the GPS receiver 108 described in the computing device 100 of FIG. 1. In further examples, the GPS 220 may also output timing signals as received from GPS satellites or other network entities. Such timing signals may be used to synchronize collected data from sensors across multiple devices that include the same satellite timestamps.

The Wi-Fi/NFC/Bluetooth sensor 222 may include wireless communication components configured to operate according to Wi-Fi and Bluetooth standards, as discussed above with the computing device 100 of FIG. 1, and according to NFC standards to establish wireless communication with another device via contact or coming into close proximity with the other device.

The projector 224 may be or include a structured light projector that has a laser with a pattern generator to produce a dot pattern in an environment. The projector 224 may be configured to operate in conjunction with the RS camera 210 to recover information regarding depth of objects in the environment, such as three-dimensional (3D) characteristics of the objects. For example, the RS camera 210 may be an RGB-IR camera that is configured to capture one or more images of the dot pattern and provide image data to the depth processor 228. The depth processor 228 may then be configured to determine distances to and shapes of objects based on the projected dot pattern. By way of example, the depth processor 228 may be configured to cause the projector 224 to produce a dot pattern and cause the RS camera 210 to capture an image of the dot pattern. The depth processor may then process the image of the dot pattern, use various algorithms to triangulate and extract 3D data, and output a depth image to the co-processor 230.

The temperature sensor 226 may be configured to measure a temperature or temperature gradient, such as a change in temperature, for example, of an ambient environment of the computing device 200.

The co-processor 230 may be configured to control all sensors on the computing device 200. In examples, the co-processor 230 may control exposure times of any of cameras 208, 210, and 212 to match the IR flash 214, control the projector 224 pulse sync, duration, and intensity, and in general, control data capture or collection times of the sensors. The co-processor 230 may also be configured to process data from any of the sensors into an appropriate format for the application processor 232. In some examples, the co-processor 230 merges all data from any of the sensors that corresponds to a same timestamp or data collection time (or time period) into a single data structure to be provided to the application processor 232. The co-processor 230 may also be configured to perform other functions, as described below.

The application processor 232 may be configured to control other functionality of the computing device 200, such as to control the computing device 200 to operate according to an operating system or any number of software applications stored on the computing device 200. The application processor 232 may use the data collected by the sensors and received from the co-processor to perform any number of types of functionality. The application processor 232 may receive outputs of the co-processor 230, and in some examples, the application processor 232 may receive raw data outputs from other sensors as well, including the GS camera 208 and the RS camera 210. The application processor 232 may also be configured to perform other functions, as described below.

The second IMU 234 may output collected data directly to the application processor 232, which may be received by the application processor 232 and used to trigger other sensors to begin collecting data. As an example, outputs of the second IMU 234 may be indicative of motion of the computing device 200, and when the computing device 200 is in motion, it may be desired to collect image data, GPS data, etc. Thus, the application processor 232 can trigger other sensors through communication signaling on common buses to collect data at the times at which the outputs of the IMU 234 indicate motion.

The computing device 200 shown in FIG. 2 may include a number of communication buses between each of the sensors and processors. For example, the co-processor 230 may communicate with each of the IMU 202, the GS camera 208, and the RS camera 212 over an inter-integrated circuit (I2C) bus that includes a multi-master serial single-ended bus for communication. The co-processor 230 may receive raw data collected, measured, or detected by each of the IMU 202, the GS camera 208, and the RS camera 212 over the same I2C bus or a separate communication bus. The co-processor 230 may communicate with the application processor 232 over a number of communication buses including a serial peripheral interface (SPI) bus that includes a synchronous serial data link that may operate in full duplex mode, the I2C bus, and a mobile industry processor interface (MIPI) that includes a serial interface configured for communicating camera or pixel information. Use of various buses may be determined based on need of speed of communication of data as well as bandwidth provided by the respective communication bus, for example.

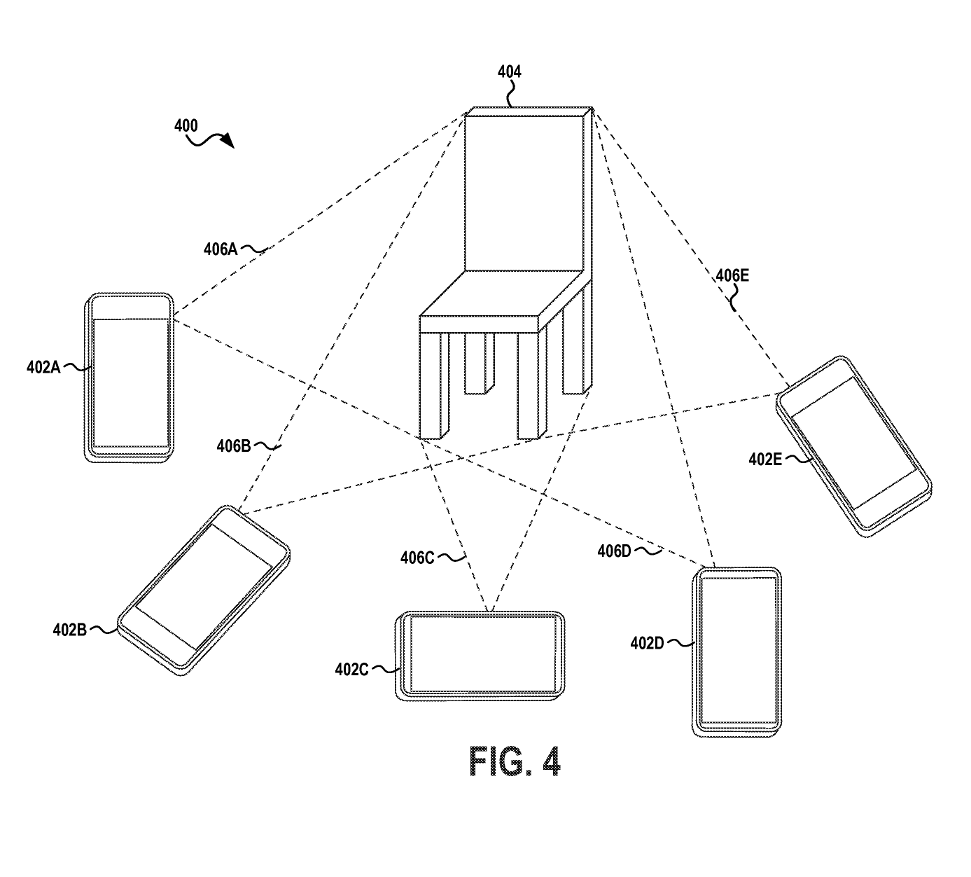

FIG. 4 is a conceptual illustration of a scenario 400 where mobile device 402 is capturing image data of a chair 404. In embodiments presented herein, the mobile device 402 may capture one more images with each image containing the same object, such as chair 404 of FIG. 4. The mobile device 402 may capture image data of the chair from various angles and in various orientations, as shown by representations 402A-402E of mobile device 402. At each position where an image is captured, each representation 402A-402E of mobile device 402 may have an associated field of view 406A-406E. Within each field of view 406A-406E, the camera of the mobile device may be able to see the target object 404.

Additionally, when the mobile device 402 captures image data, it may also store associated sensor data. For example, the mobile device 402 may capture sensor data at the position of each representation 402A-402E where a photo is captured. In other embodiments, the mobile device 402 may capture sensor data continuously as each image corresponding to the positions of representation 402A-402E is captured.

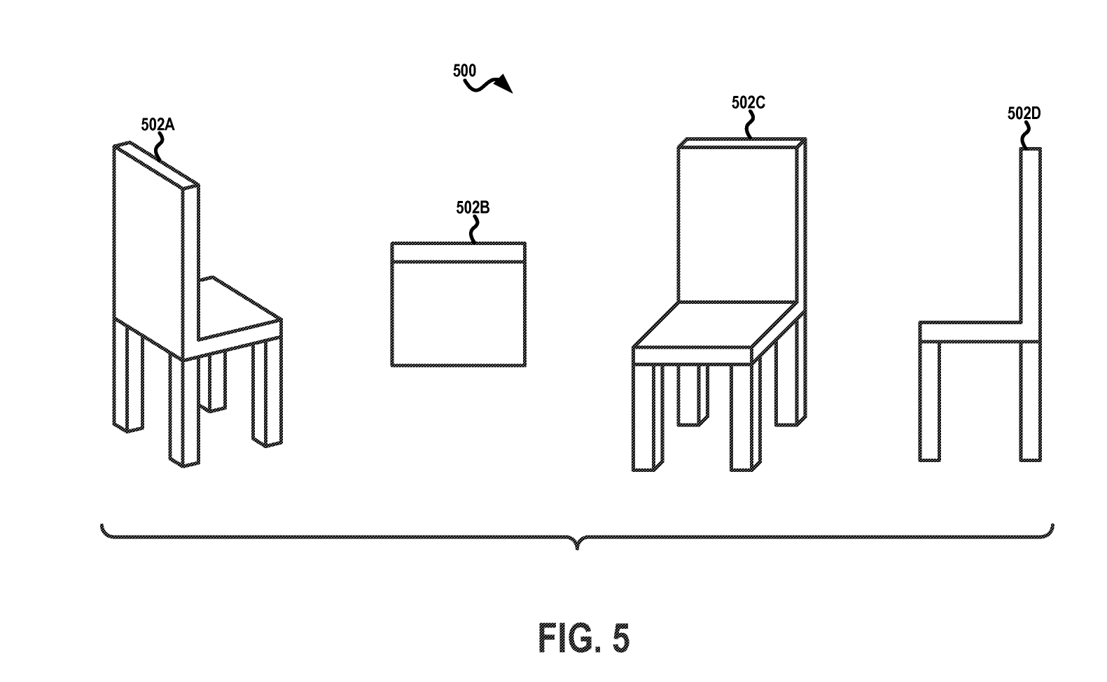

FIG. 5 represents renderings of three-dimensional object data 500 for a chair. The three-dimensional object data may be stored within a mobile device. The mobile device may compare an image captured by the mobile device with the three-dimensional object data. For example, if a chair is viewed from different angles, the chair may appear differently. Thus, three-dimensional object data 500 is shown rendered in many different views of the chair. As shown in FIG. 5, views 502A-502D each show the chair from a different angle. In some further examples, three-dimensional object data 500 of the chair may also include color information about the chair.

When the mobile device captures an image containing the chair, the mobile device may use three-dimensional object data 500 of the chair to determine parameters of the picture. For example, based on the size and orientation of the chair, the mobile device may be able to calculate some position information about the location of the mobile device relative to the chair. If a second picture is captured, the mobile device may be able to calculate some position information about the location of the mobile device when it captured the second picture. Based on the two images, the mobile device may be able to determine a movement, orientation, or other sensor parameter based on analyzing the chair in each picture. The mobile may compare this determined movement, orientation, or other sensor parameter with captured sensor data. Therefore, a calibration value may be calculated based on the difference between the determined movement, orientation, or other sensor parameter and the captured sensor data.

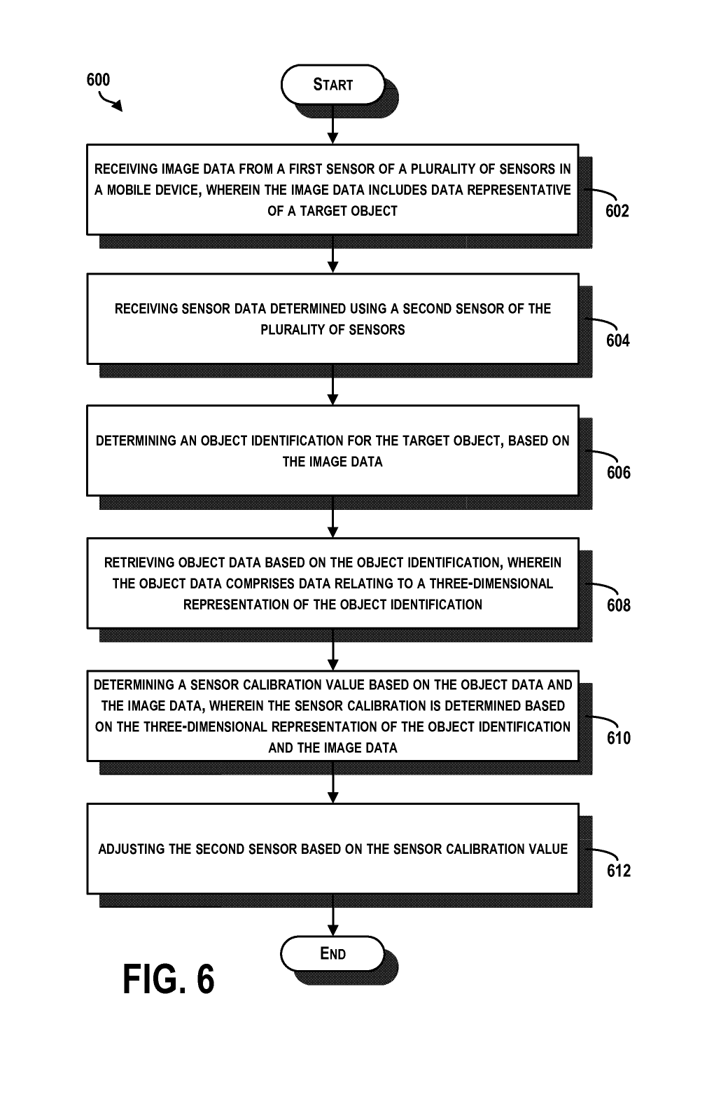

FIG. 6 is a block diagram of an example method 600 for device sensor calibration. Method 600 shown in FIG. 6 presents an embodiment of a method that could be used or implemented by the computing device 100 of FIG. 1 or the computing device 200 of FIG. 2, for example, or more generally by one or more components of any computing device. Method 600 may include one or more operations, functions, or actions as illustrated by one or more of blocks 602-614. Although the blocks are illustrated in a sequential order, these blocks may also be performed in parallel, and/or in a different order than those described herein. Also, the various blocks may be combined into fewer blocks, divided into additional blocks, and/or removed based upon the desired implementation.

In addition, for the method 600 and other processes and methods disclosed herein, the block diagram shows functionality and operation of one possible implementation of present embodiments. In this regard, each block may represent a module, a segment, or a portion of program code, which includes one or more instructions executable by a processor or computing device for implementing specific logical functions or steps in the process. The program code may be stored on any type of computer-readable medium, for example, such as a storage device including a disk or hard drive. The computer-readable medium may include non-transitory computer-readable medium, for example, such as computer-readable media that stores data for short periods of time like register memory, processor cache and random access memory (RAM). The computer-readable medium may also include non-transitory media, such as secondary or persistent long term storage, like read only memory (ROM), optical or magnetic disks, compact-disc read only memory (CD-ROM), for example. The computer-readable media may also be any other volatile or non-volatile storage systems. The computer-readable medium may be considered a computer-readable storage medium, for example, or a tangible storage device.

In addition, for the method 600 and other processes and methods disclosed herein, each block in FIG. 6 may represent circuitry that is wired to perform the specific logical functions in the process.

Functions of the method 600 may be fully performed by a computing device, or may be distributed across multiple computing devices and/or servers. As one example, the method 600 may be performed by a device that has an application processor configured to function based on an operating system and a co-processor configured to receive data from a plurality of sensors of the device. The sensors may include any sensors as described above in any of FIG. 1, FIG. 2, or FIGS. 3A-3B, for example, including an IMU, a global shutter camera, a rolling shutter camera, a structured light projector, a depth camera, an infrared flash, a barometer, a magnetometer, and a temperature sensor. It is contemplated that the sensors may include other types of sensors as well. The method 600 may also include image capturing, similar to that disclosed with respect to FIG. 4. Further, the method 600 may also incorporate three-dimensional object data, similar to that described with respect to FIG. 5.

In some embodiments, functions of the method 600 may be performed by the application processor 232 of FIG. 2. In other embodiments, functions of the method 600 may be performed by the co-processor 230 of FIG. 2. In still other embodiments, functions of the method 600 may be performed by a computing device that is located remotely from the mobile device. In some embodiments, the remote computing device may be in a server.

Initially, at block 602, the method 600 includes receiving image data from a first sensor of a plurality of sensors in a mobile device. In some examples, the image data may include data representative of a target object. For instance, the image data may be two-dimensional or three-dimensional image data captured using a camera or depth processor of the mobile device. Within examples, the image data may be received from a camera of the mobile device, or received from the co-processor of the mobile device. Additionally, the image data may also include data from multiple captured images and/or captured video.

The image data may include data representative of a target object the mobile device may have been captured while a position and/or orientation of the mobile device is manipulated. For example, the image data may have been captured while a user rotates the mobile device or varies the position of the mobile device. However, in other embodiments, the mobile device at a single location, without the device being moved, may capture the image data.

In one embodiment, the image data may be a sequence of images, such as three, five, ten, or another number of images captured in sequence. In another embodiment, the image data may be captured as video.

The captured image data may include data representative of a target object in each image (or video). In some examples, the various images that make up the image data may include the same target object. For instance, the various images of the captured image data may each include a chair. The chair may be imaged from different positions and angles. Thus, the chair may be represented in each image and it may not appear exactly the same (due to the mobile capturing the images from various positions and with various orientations). In additionally embodiments, more than one target object may be captured in the image data.

At block 604, the method 600 includes receiving sensor data from the second sensor of the plurality of sensors. The sensor data may also correspond to the same motion of the mobile device described above. Additionally, the sensor data may have been determined using a second sensor of the mobile device at the time when one or more of the images of the image data was captured. Within examples, the sensor data may be received from the co-processor or received from the sensor of the mobile device.

In one instance, the sensor data may include accelerometer readings from a gyroscope, IMU, magnetometer, or accelerometer of the mobile device. The sensor data may also include movement information based on GPS, dead reckoning, or other form of localization. In another instance, the sensor data may include images representative of the motion of the mobile device that were captured using a second camera of the mobile device. In still another instance, the sensor data may include a sequence of depth images determined using a depth processor of the mobile device. In yet another instance, the sensor data may include ambient light measurements provided by a light sensor of the mobile device. In further embodiments, the sensor data may include color data provided by a camera of the mobile device. For example, in some embodiments, both the first sensor and the second sensor may both be camera units. In further embodiments, a camera sensor may function as both the first sensor and the second sensor.

The sensor data may be captured at the same time an image of the image data is captured, shortly before or after an image is captured, continuously while image captures are occurring, or with a different timing. In one specific example, sensor data may be captured when a first image is captured and data may continuously captured from the sensor until a second image is captured. In another embodiment, sensor data may be captured simultaneously with each image capture.

At block 606, the method 600 includes determining an object identification for the target object, based on the image data. In various embodiments, block 606 may be performed either locally or by a remote computing device. In embodiments where block 606 is performed locally, the mobile device may have an object database. The mobile may compare the data representative of the target object to objects in the database to determine an object identification. For example, the image may be analyzed to determine what objects are present in the image. Once objects are identified, a target object may be identified based on various criteria. In some embodiments the target object is identified by the object's placement within the image. In other embodiments, a plurality of objects may be analyzed and any recognized object may be the target object that is identified.

In other embodiments, the mobile device may communicate at least a subset of the image data to a server. The server may be able to identify the target object based on the image data. The server may then responsively communicate the object identification to the mobile device. In yet further embodiments, the mobile device may attempt to identify the target object on its own, if it cannot identify the target object, it may communicate at least a portion of the image data to the server to perform the identification.

At block 608, the method 600 includes retrieving object data based on the object identification. The object data may include data relating to a three-dimensional representation of the object identification. Once an object has been identified, the mobile can retrieve object data about the identified object. In various embodiments, the retrieving of block 608 may be performed either locally retrieving from a memory of the mobile device or by querying a remote computing device. In some embodiments, the mobile device may first check a local device memory for the object data, if the local memory does not have object data, the mobile device may responsively query the remote computing device.

The object data may include data relating to a three-dimensional representation of the identified object, similar to that discussed with respect to FIG. 5. For example, the object data may be a 3D model of the object that was captured as part of the image data. The object data may also include color information about the identified object. The object data may be obtained in various ways. For example, a database may contain detailed measurement and size data for the object. When an object is identified, the database may be queried to retrieve the object data.

In one example, a server may contain a library of object data. The server may periodically communicate object data to the mobile device. Object data communicated to the mobile may be based on objects that are likely to be captured in an image by the mobile device. The server may determine objects that are likely to be captured in an image in a variety of ways. In one example, object data for common household objects may be communicated to the mobile device. In another example, object data for objects that an owner of mobile device is known to possess may be communicated to the mobile device. In yet another example, object data may be communicated to the mobile device based on an image captured by a different mobile device. In this example, a different mobile device may either capture an image or identify objects and communicate the image or object information to a server. The server may determine that the other mobile device is likely to encounter the same objects and communicate the object data to the mobile device.

At block 610, the method 600 includes determining a predicted sensor value based on the based on the object data and the image data. Because the object data contains a three-dimensional representation of the object, the object data can function as a reference for calibration. For examples, the predicted sensor value may be determined by comparing the object data to data representative of the target object in the image data. To determine the predicted value, the image data is analyzed along with the object data to predict what a sensor should output if the sensor is operating correctly.

In one embodiment, the size, shape, and position of the target object in a first image of the image data, may be compared to the object data. Based on this comparison, the distance, angle, orientation, color, or other attributes of the target object related to the mobile device may be calculated. The comparison may be repeated based on a second image of the image data. Thus, the two comparisons based on the object data acting as a reference, allows predicted sensor values to be calculated for a movement of the mobile device between the position where the first image was captured and a position where the second image was captured.

Additionally, in some embodiments, the object data may include color information. In these embodiments, the color information can act at as a reference for calibration. Additionally, a light level sensor may act as the second sensor in color information embodiments. Thus, in these embodiments, the sensor adjustment may be able to correctly adjust a color output of a camera of the mobile device.

At block 612, the method 600 includes determining a sensor calibration value based on a different between the received sensor data and the predicted sensor value. The sensor calibration value may be calculated either by the mobile device, by the remote server, or a combination of both.

The predicted sensor values can then be compared to the measure sensor values to determine an offset of the sensor calibration value. This offset represents the difference between measured values in the mathematical correct values, and may be the calibration value. For example, based on an analysis of two captured images, it may be determined that a mobile device moved 8 inches right between the two pictures. The sensor data may indicate the device only moved 6 inches. Thus, the difference of two inches may be used to calculate the sensor offset. In some embodiments, the sensor offset may be calculated to be 33% increase in sensor data (as 2 inches is 33% of the 6 inches reported by the sensor).

In other embodiments, the calibration may be performed for an imaging element of the mobile device. In this embodiment, color information from the object maybe compared with the color captured for the target object. This calibration may be performed with only a single captured image in the image data. However, in some examples, the target object may be captured in various lighting conditions. The calibration may be performed across the various images with the different lighting conditions. For example, an image may include a chair having a specific shade of white. However, the object data may indicate the chair is actually a different shade of white. The sensor offset may be determined to correctly image the white color of the chair.

In yet another embodiment, the calibration may be performed based on a single image captured by a second mobile device, where a first mobile device captured in image of the target device. The first mobile device to capture an image of the target object, and also store associated sensor data when capturing the image. This image and sensor data may be communicated to either a server or the other mobile device. The second mobile device, may also capture an image of the target object and associated sensor data. The comparison may then be made between images captured from two different devices and sensor data captured from two different devices. This comparison may still be used to calculate the calibration value for the second device, as position information between the two images may be calculated based on the sensor information. For example, a calibrated first device may take a picture of the chair from a known position. The second device may not be calibrated and it may also take a picture of the same chair. Based on a calculation of the two images, a movement, a GPS location, or other parameters for sensors of the second device may be calculated.

For a further example, in an example in which the image data includes a sequence of two-dimensional images, the estimation of motion of the mobile device may include an estimate of a rotational motion of the mobile device. Such an estimate of a rotational motion of the mobile device may be derived by calculations based on the sensor data. The estimate of rotational motion of the mobile may be compared to a reference movement where the reference movement is based on identifying a target object in the images and tracking movement of the location of the target object within each image throughout the sequence of images. For example, based on an analysis of two of the captured images, it may be determined that a mobile device rotated 90 degrees between the two pictures. The sensor data may indicate the device only moved 85 degrees. Thus, the difference of 5 degrees may be used to calculate the sensor offset.

In another example, the reference motion of the mobile device may include a trajectory of the mobile device. For instance, if the mobile device is moved in front of a known target object, a trajectory of the mobile device over time may be determined based on the observations of the known object or target. The trajectory may include one or any combination of position and orientation estimates of the mobile device over time within a frame of reference of the known object or target. The reference trajectory may be compared to the trajectory determined based on the sensor values to determine the sensor calibration value. The trajectory may be used to calculate sensor offsets similar as described for device movement.

At block 614, the method 600 includes adjusting the second sensor based on the sensor calibration value. The second sensor may be adjusted based on the sensor calibration value. Depending on the type of sensor or the sensor offset, the adjustment may be made in a variety of different ways. In some embodiments, the sensor may have a fixed offset adjustment. In other embodiments, the sensor may have an offset that adjusts based on the value of the sensor. In yet further embodiments, the sensor calibration value may be determined based on a mathematical relationship between the sensor value and the expected value. In some embodiments, blocks 602-612 may be repeated several times to create the sensor calibration value. Additionally, blocks 602-612 may be repeated to confirm the adjusted second sensor value gives a sensor value similar to that calculated based on an analysis of the images.

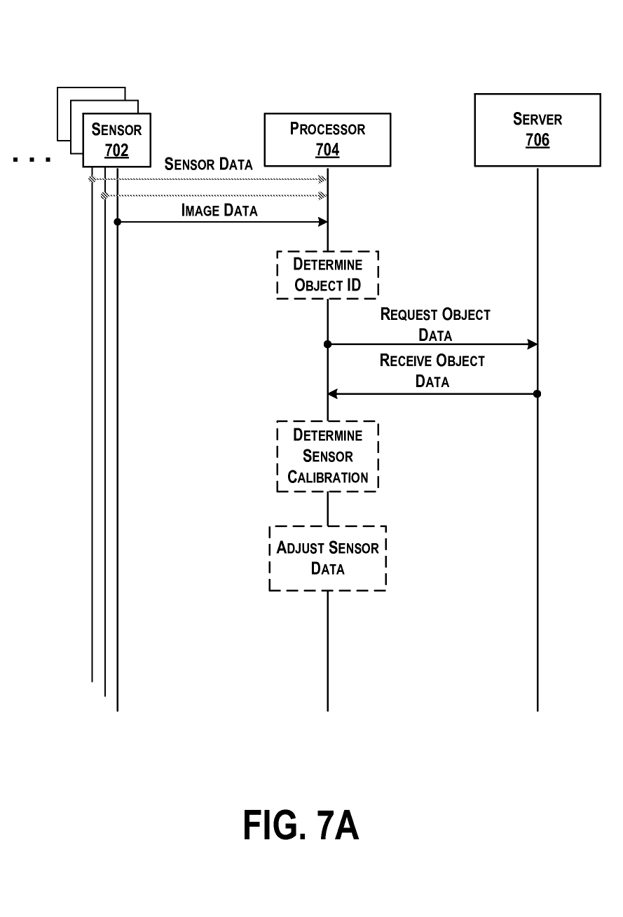

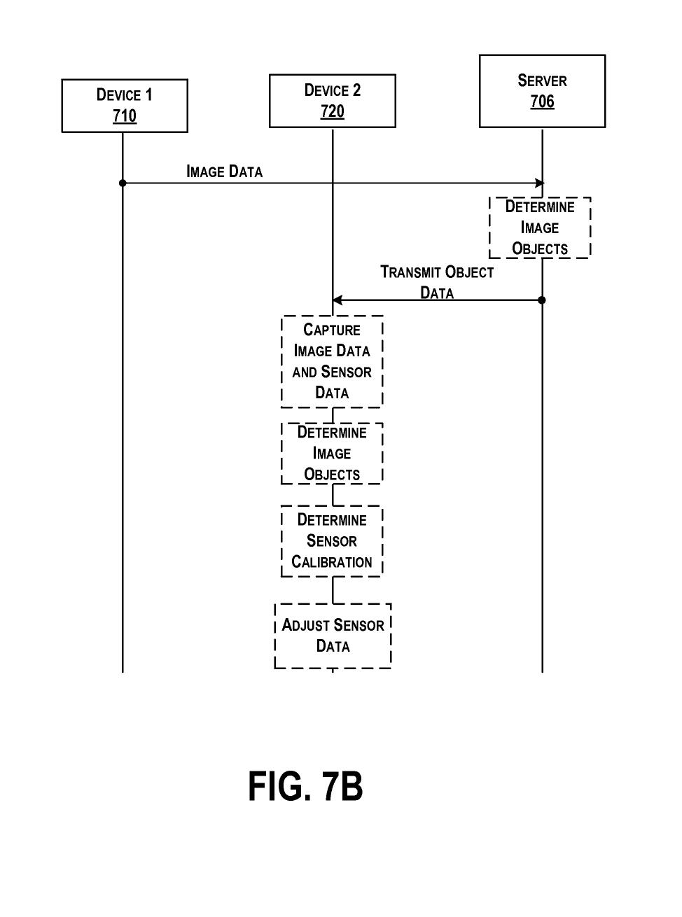

Turning now to FIGS. 7A and 7B, flow diagrams for different embodiments of the methods disclosed herein are disclosed. FIG. 7A discloses a flow diagram for a single mobile device performing an embodiment of method 600. FIG. 7B discloses a flow diagram for a two mobile device performing an embodiment of method 600 together.

In FIG. 7A, a group of sensors 702 are coupled to a processor 704. Both the sensors and the processor may be located in a mobile device. The server 706 may be located remote from, but in communication with, the mobile device. The group of sensors 702 may generate data for communication to the processor 704. The processor 704 may receive both sensor data and image data from the group of sensors 702.

Based on the received data from the group of sensors 702, the processor may determine an object identification for a target object. The object identification for then target object may be determined based on the image data from the group of sensors 702. In some embodiments (not pictured), the processor 704 may not be able to determine an object identification for then target object. In this case, the image data from the group of sensors may be communicated to the server 706 to determine the object identification.

Once an object identification is determined by the processor 704, the processor 704 can communicate a request for object data to the server 706. The processor 704 may responsively receive object data from the server 706. In embodiments where the server 706 determines the object identification, the processor may not communicate a request for object data to the server 706, but rather it may receive object data from the server 706 after the server 706 determines the object identification.

In response to the processor 704 receiving object data from the server 706, the processor 704 may determine a sensor calibration. The processor 704 may determine the sensor calibration in a similar manner to the discussion related to FIG. 6 above, including blocks 610 and 612. Similarly, the processor 704 may adjust the sensor data based on the sensor calibration as previously discussed with respect to FIG. 6 above.

In FIG. 7B, Device 1 710 is in communication with a server 706. The server 706 is also in communication with Device 2 720. In the embodiment shown in FIG. 7B, two devices may be used to aid the second device in performing its sensor calibration. Device 1 710 may capture image data of an area, such as inside an office. Device 1 710 may responsively transmit the image data to Server 706. Once Server 706 received the image data from Device 1 710, it will determine target objects in the image. The Server 706 will also transmit object data for the determined objects to Device 2 720. Thus, Device 2 720 may be able to store local copies of the object data before it ever determines what objects are present in an image. Additionally, after Device 2 720 stores local copies of the object data, it may be able to perform method 600 without using any external network connections.

Device 2 720 may then capture image and sensor data from a group of sensors are coupled to a processor in Device 2. The image captured may be an image of the same office as what was captured by Device 1 710. Both the sensors and the processor may be located in a mobile device. Based on the received data from the group of sensors, the processor of Device 2 720 may determine an object identification for a target object. The object identification for then target object may be determined based on the image data from the group of sensors.

Once an object identification is determined by the processor, the processor can look up object data that has been provided to Device 2 720 from the server 706. In response to the processor looking up the object data, the processor may determine a sensor calibration. The processor may determine the sensor calibration in a similar manner to the discussion related to FIG. 6 above, including blocks 610 and 612. Similarly, the processor may adjust the sensor data based on the sensor calibration as previously discussed with respect to FIG. 6 above.

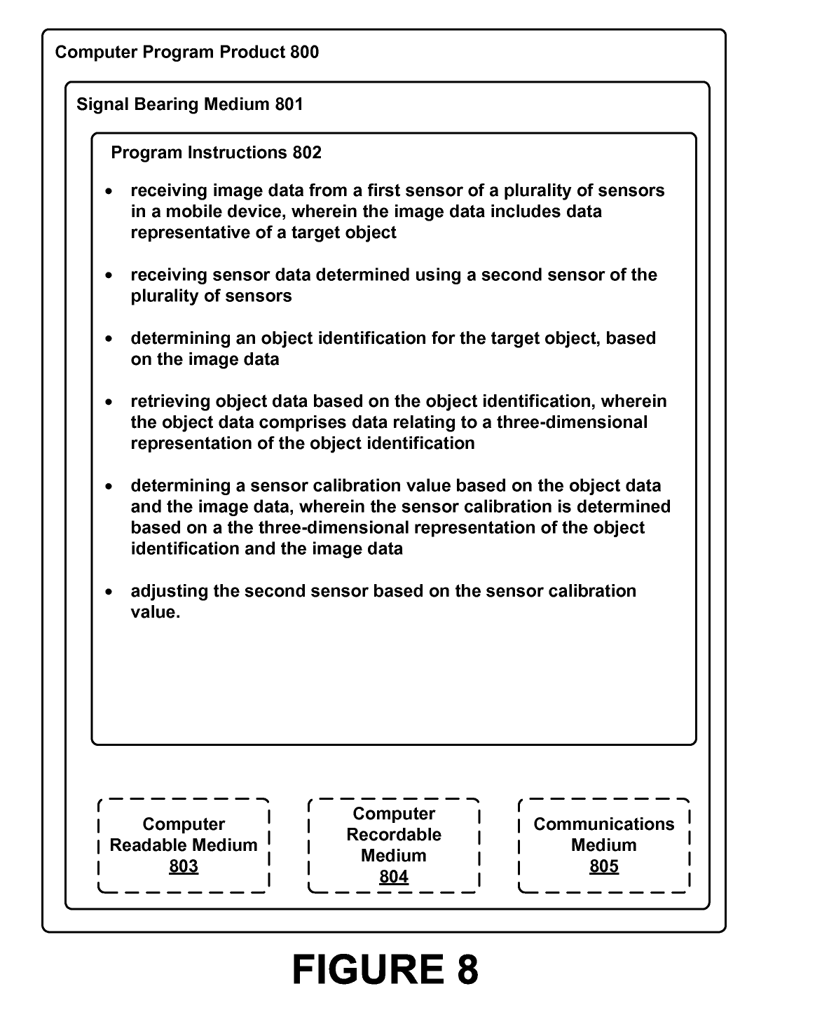

In some embodiments, the disclosed methods may be implemented as computer program instructions encoded on a non-transitory computer-readable storage media in a machine-readable format, or on other non-transitory media or articles of manufacture. FIG. 8 is a schematic illustrating a conceptual partial view of an example computer program product 300 that includes a computer program for executing a computer process on a computing device, arranged according to at least some embodiments presented herein.

In one embodiment, the example computer program product 800 is provided using a signal bearing medium 801. The signal bearing medium 801 may include one or more programming instructions 802 that, when executed by one or more processors may provide functionality or portions of the functionality described above with respect to FIGS. 1-12. In some examples, the signal bearing medium 801 may encompass a computer-readable medium 803, such as, but not limited to, a hard disk drive, a Compact Disc (CD), a Digital Video Disk (DVD), a digital tape, memory, etc. In some implementations, the signal bearing medium 801 may encompass a computer recordable medium 804, such as, but not limited to, memory, read/write (R/W) CDs, R/W DVDs, etc. In some implementations, the signal bearing medium 801 may encompass a communications medium 806, such as, but not limited to, a digital and/or an analog communication medium (e.g., a fiber optic cable, a waveguide, a wired communications link, a wireless communication link, etc.). Thus, for example, the signal bearing medium 801 may be conveyed by a wireless form of the communications medium 806 (e.g., a wireless communications medium conforming to the IEEE 802.11 standard or other transmission protocol).

The one or more programming instructions 802 may be, for example, computer executable and/or logic implemented instructions. In some examples, a computing device such as the computing device 100 of FIG. 1 may be configured to provide various operations, functions, or actions in response to the programming instructions 802 conveyed to the computing device 100 by one or more of the computer-readable medium 803, the computer recordable medium 804, and/or the communications medium 806.

It should be understood that arrangements described herein are for purposes of example only. As such, those skilled in the art will appreciate that other arrangements and other elements (e.g. machines, interfaces, functions, orders, and groupings of functions, etc.) can be used instead, and some elements may be omitted altogether according to the desired results. Further, many of the elements that are described are functional entities that may be implemented as discrete or distributed components or in conjunction with other components, in any suitable combination and location.

While various aspects and embodiments have been disclosed herein, other aspects and embodiments will be apparent to those skilled in the art. The various aspects and embodiments disclosed herein are for purposes of illustration and are not intended to be limiting, with the true scope being indicated by the following claims, along with the full scope of equivalents to which such claims are entitled. It is also to be understood that the terminology used herein is for the purpose of describing particular embodiments only, and is not intended to be limiting.

What is claimed is:

1. A method, comprising:
receiving image data from a first sensor of a plurality of sensors in a mobile device, wherein the image data includes data representative of a target object;
receiving sensor data determined using a second sensor of the plurality of sensors;
determining an object identification for the target object, based on the image data;
retrieving object data based on the object identification, wherein the object data comprises data relating to a three-dimensional representation of the object identification;
comparing the object data to the data representative of the target object in the image data so as to determine a predicted sensor value to be output from the second sensor corresponding to the first sensor outputting the image data;
determining a sensor calibration value based on a difference between the received sensor data and the predicted sensor value; and
adjusting the second sensor based on the sensor calibration value.

2. The method of claim 1, wherein:
the image data comprises a sequence of two-dimensional images;
a first image of the sequence and a second image of the sequence both contain data representative of the target object;
an image-capture location of the first image is different than an image-capture location of the second image; and
the received sensor data comprises data related to a movement between the image-capture location of the first image and the image-capture location of the second image.

3. The method of claim 1, wherein the object data comprises color data associated with the object identification, and wherein the sensor calibration value is based on a difference between the color data associated with the object identification and a color data of the data representative of the target object.

4. The method of claim 1, wherein a processor of the mobile device performs the determining the object identification, comparing the object data to the data representative of the target object, and determining a sensor calibration value.

5. The method of claim 1, wherein determining the object identification comprises:
communicating at least a subset of the image data to a remote server; and
receiving data indicative of the object identification from the remote server.

6. The method of claim 1, wherein the object data is retrieved based on image data communicated to a server from a second mobile device.

7. The method of claim 1, further comprising:
determining an object identification for a second target object, based on the image data, wherein the image data includes data representative of the second target object;
retrieving second object data based on the object identification; and
determining the predicted sensor value based on the object data, the second object data, and the image data, wherein the predicted sensor value is determined by comparing both:
(i) the object data to data representative of the target object in the image data, and
(ii) the second object data to data representative of the second target object in the image data.

8. A mobile device comprising:
at least one camera configured to capture image data;
at least one sensor; and
a processor, the processor configured to:
receive image data from the at least one camera, wherein the image data includes data representative of a target object;
receive sensor data determined using the at least one sensor;
determine an object identification for the target object based on the image data;
retrieve object data based on the object identification, wherein the object data comprises data relating to a three-dimensional representation of the object identification;
compare the object data to the data representative of the target object in the image data so as to determine a predicted sensor value to be output from the second sensor corresponding to the first sensor outputting the image data;
determine a sensor calibration value based on a difference between the received sensor data and the predicted sensor value; and
adjust the at least one sensor based on the sensor calibration value.

9. The mobile device of claim 8, wherein:
the image data comprises a sequence of two-dimensional images;
a first image of the sequence and a second image of the sequence both contain data representative of the target object;
an image-capture location of the first image is different than an image-capture location of the second image; and
the received sensor data comprises data related to a movement between the image-capture location of the first image and the image-capture location of the second image.

10. The mobile device of claim 8, wherein the object data comprises color data associated with the object identification, and wherein the sensor calibration value is based on a difference between the color data associated with the object identification and a color data of the data representative of the target object.

11. The mobile device of claim 8, wherein determining the object identification comprises the processor being further configured to:
communicating at least a subset of the image data to a remote server; and
receiving data indicative of an object identification from the remote server.

12. The mobile device of claim 8, wherein the object data is retrieved based on image data communicated to a server from a second mobile device.

13. The mobile device of claim 8, further comprising the processor being further configured to:
determine an object identification for a second target object, based on the image data, wherein the image data includes data representative of the second target object;
retrieve second object data based on the object identification; and
determine the predicted sensor value based on the object data, the second object data, and the image data, wherein the predicted sensor value is determined by comparing both:
(i) the object data to data representative of the target object in the image data, and
(ii) the second object data to data representative of the second target object in the image data.

14. An article of manufacture including a non-transitory computer-readable medium having stored thereon instructions that, when executed by a processor in a system, cause the system to perform operations comprising:
receiving image data from a first sensor of a plurality of sensors in a mobile device, wherein the image data includes data representative of a target object;
receiving sensor data determined using a second sensor of the plurality of sensors;
determining an object identification for the target object, based on the image data;
retrieving object data based on the object identification, wherein the object data comprises data relating to a three-dimensional representation of the object identification;
comparing the object data to the data representative of the target object in the image data so as to determine a predicted sensor value to be output from the second sensor corresponding to the first sensor outputting the image data;
determining a sensor calibration value based on a difference between the received sensor data and the predicted sensor value; and
adjusting the second sensor based on the sensor calibration value.

15. The article of manufacture of claim 14, wherein:
the image data comprises a sequence of two-dimensional images;
a first image of the sequence and a second image of the sequence both contain data representative of the target object;
an image-capture location of the first image is different than an image-capture location of the second image; and
the received sensor data comprises data related to a movement between the image-capture location of the first image and the image-capture location of the second image.

16. The article of manufacture of claim 14, wherein the object data comprises color data associated with the object identification, and wherein the sensor calibration value is based on a difference between the color data associated with the object identification and a color data of the data representative of the target object.

17. The article of manufacture of claim 14, wherein a processor of the mobile device performs the determining the object identification, comparing the object data to the data representative of the target object in the image data, and determining a sensor calibration value.

18. The article of manufacture of claim 14, wherein determining the object identification comprises:
communicating at least a subset of the image data to a remote server; and
receiving data indicative of an object identification from the remote server.

19. The article of manufacture of claim 14, wherein the object data is retrieved based on image data communicated to a server from a second mobile device.

20. The article of manufacture of claim 14, further comprising:
determining an object identification for a second target object, based on the image data, wherein the image data includes data representative of the second target object;
retrieving second object data based on the object identification; and
determining the predicted sensor value based on the object data, the second object data, and the image data, wherein the predicted sensor value is determined by comparing both:
(i) the object data to data representative of the target object in the image data, and
(ii) the second object data to data representative of the second target object in the image data.
